(19) United States
(12) Patent Application Publication
(10) Pub. No.: US 2015/0364635 A1
(43) Pub. Date: Dec. 17, 2015

(54) SINGLE PHOTON COUNTING

(71) Applicant: Malvern Instruments Limited, Malvern, Worcestershire (GB)

(72) Inventors: Roland BODLOVIC, Malvern (GB); Gerald COOK, Malvern (GB); Robert JACK, Malvern (GB)

(73) Assignee: MALVERN INSTRUMENTS LIMITED, Malvern, Worcestershire (GB)

(21) Appl. No.: 14/764,550

(22) PCT Filed: Jan. 30, 2014
(86) PCT No.: PCT/GB2014/050241

§ 371 Date: Jul. 29, 2015

(30) Foreign Application Priority Data
Jan. 31, 2013 (GB) 1301754.6

(51) Int. Cl. H01L 31/107

(52) U.S. Cl. CPC H01L 31/107

(57) ABSTRACT

A single photon counting apparatus comprising a SPAD and a controller. The controller is operable to vary the operating parameters of the SPAD during use in response to a count rate detected by the SPAD. The operating parameters comprising at least one of the voltage across the SPAD during an active period, the voltage across the SPAD during a quench period, the duration of the quench period and the temperature of the SPAD. Particle characterisation instruments comprising the apparatus are also disclosed.

This invention relates to methods and apparatus for single photon counting, for example in dynamic light scattering measurements for particle characterisation.

A number of commercial single photon counting systems (or modules) are available which convert the energy in a single photon into an electronic signal useable by standard type electronic inputs (such as TTL, LVCMOS etc).

Photon counting typically relies on a specially designed photodiode which is capable of being reverse biased above its breakdown voltage. Once the diode is biased in this way it becomes extremely sensitive to incident photons due to a process of electron avalanching triggered by the photon ionisation. Charge carriers are released and accelerated in the high electric field causing further ionisation and more electron hole pairs. This cascaded process continues until substantial current flows in the diode. This current is detectable by an input of a trigger type semi-conductor device (such as a comparator).

Such a photodiode may be referred to as a “Geiger-mode avalanche photo diode” or “Single Photon Avalanche Diode (SPAD)”. A SPAD may be distinguished from an Avalanche Photo Diode, or APD. In an APD, the bias voltage is kept below the breakdown voltage, so that it performs as a linear amplifier for the input optical signal. Each photon may produce a few tens or hundreds of electrons, and this process is not diverging. This is in contrast with a SPAD, which may be triggered into a self-sustaining cascade by a single photon.

Examples of avalanche photodiodes, which may be operated in Geiger-mode (i.e. with a bias voltage above the breakdown voltage) include Laser Components SAP500 and Excelitas C30902SH.

The SPAD may form the detector of a single photon counting system but requires careful control due to the nature of such a device. Once a photon causes an avalanche, the device current can rapidly rise within a few nanoseconds to a level where it destroys the SPAD. The current must be therefore be limited and the avalanche must be stopped (or quenched) as soon as possible to prevent the destruction of the SPAD. This is typically achieved by reducing the voltage across the diode to below the breakdown (or threshold) voltage.

In the context of photon counting, the time that a SPAD spends being inactive is known as dead time. Dead time is the time from the moment a photon strikes the SPAD causing an avalanche, to the moment the voltage across the SPAD rises above its breakdown voltage after it has been quenched. It is not possible to detect a photon during the dead time and thus dead time may cause a reduction in linearity for a photon counting instrument at high count rates. Any photons striking the SPAD during the dead time will not be detected.

Another source of error in photon counting systems is termed dark count. Dark count is associated with SPADs and is caused by thermally excited electron carriers in the device due to impurities in the materials. The thermally excited electrons can trigger an avalanche event, and therefore appear as a false photon detection event. Dark count noise is essentially random and is present without any light.

A further noise source with SPADs is termed after pulsing. After pulsing usually happens shortly after an avalanche event and is caused by left over charge carriers trapped in the SPAD following quenching.

A photon counting apparatus that mitigates at least some of these sources of error is desired.

There are two broad mechanisms for quenching a SPAD: passive quenching and active quenching.

Passive quenching typically limits the current using a simple series resistor. Once an avalanche occurs the current through the SPAD and the series resistor will increase. The increased current through the resistor results in an increased voltage drop over the resistor, which in turn reduces the voltage across the SPAD. Eventually, the voltage across the SPAD will dip below the breakdown voltage, and this will cause the current to subside. The voltage across the SPAD will subsequently increase back above the breakdown voltage and the SPAD will be ready to detect another photon.

Active quenching is an alternative method, which can be faster than passive quenching. In active quenching, the start of the avalanche event is detected and the voltage across the SPAD is actively removed or reduced. Circuits are known that can produce very low dead times (of the order of tens of nanoseconds).

FIG. 1 of the appended drawings illustrates a typical active quench waveform. Initially the voltage is above the breakdown or threshold voltage (Vₜₕ), by an amount Vₒᵥₑᵣ. Following an avalanche event the voltage across the diode is reduced to below Vₜₕ, by an amount V_{under}, for the quenching time, or T_{quench}. Following this quenching time, the voltage is returned to an amount Vₒᵥₑᵣ above the threshold voltage. The threshold or breakdown voltage (Vₜₕ) varies with temperature in a linear manner, and also with device properties. The quenching time may be approximately equal to the dead time, when the quench time is generally long compared with the speed of response of the quenching circuit (i.e. the time taken to reduce the voltage to below the breakdown voltage following an avalanche event). The active period for the device is the time during operation that is not dead time (i.e. where the voltage across the SPAD is greater than the breakdown voltage).

The design of a photon counting system is typically a compromise between various competing factors.

The temperature of the SPAD may be controlled, for instance by cooling and/or heating the SPAD. A lower temperature decreases the dark count but also increases the after pulse probability. As already discussed, the avalanche needs to be quenched. The longer the SPAD is quenched, the more trapped carriers are removed, which reduces the probability of after pulsing, at the cost of an increase in dead time, which may adversely affect linearity at high count rates. The voltage across the SPAD must place the SPAD in its Geiger region (above breakdown). The higher the bias voltage, the more sensitive the SPAD is to photons and the more efficient it is at detecting them. However the dark count also increases with increasing voltage.

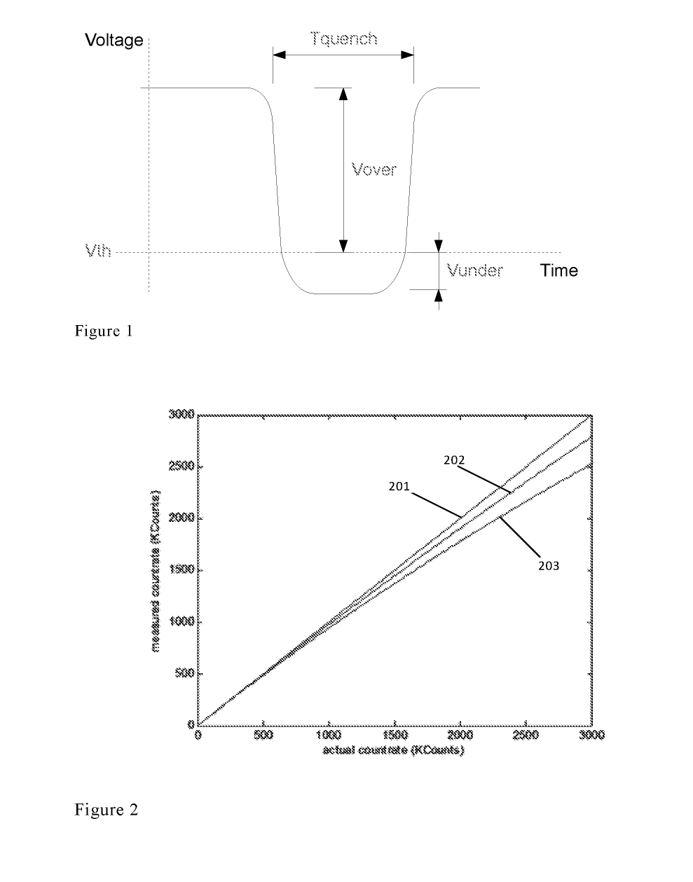

FIGS. 2 to 5b of the appended drawings illustrate some of these factors.

FIG. 2 shows the relationship between dead time and linearity. Line 201 shows a linear relationship between actual count rate (i.e. photons incident on the detector that should be detected) and measured count rate (i.e. the number of photons actually detected). Line 202 shows a similar curve for a 25 ns dead time, and line 203 shows a curve in which dead time is 62 ns.

It can be shown that the required dead time for linear operation can be calculated using:

$$n = \frac{N}{( 1 - N \frac{Dt}{T} )}$$

wherein N is the measured countrate, n is the actual count, Dt is the deadtime and T the averaging period.

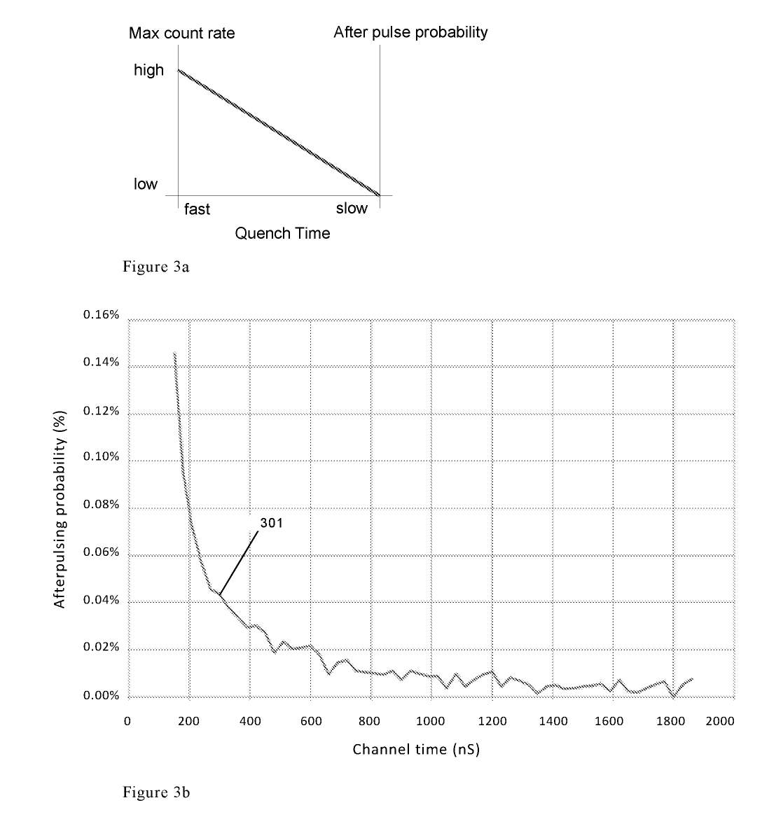

FIG. 3a shows the basic relationship between the quench time and the maximum count rate (without loss of linearity), and between the quench time and the after pulse probability. Increasing the quench time (or dead time) decreases the probability of after pulsing and reduces the maximum count rate. Decreasing the quench time increases the after pulse probability and increases the maximum count rate. For low light levels, a longer quenching time is favourable.

FIG. 3b shows a correlogram obtained from a SPAD, in which a curve 301 of after pulsing probability as a function of channel time is plotted. In this case the voltage above threshold (Vₒᵥₑᵣ) was 10V, and the temperature of the SPAD was −25° C.

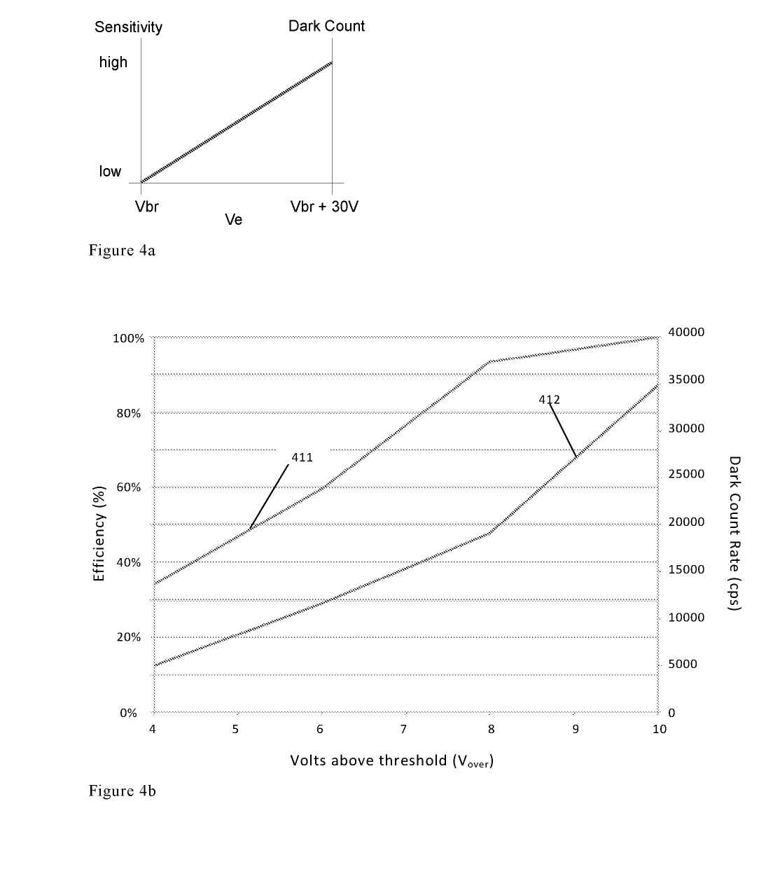

FIG. 4a shows the basic relationship between the excess bias voltage across the SPAD (over the breakdown voltage, Vₜₕ or V_{br}) and the photon sensitivity and dark count. Increasing the bias voltage (for instance to Vₒᵥₑᵣ=30V) results in increased sensitivity, and increased dark count. To some extent, this may be compensated by cooling of the SPAD. In the presence of bright light, a relatively low bias voltage is favourable.

FIG. 4b shows a curve 411 of measured efficiency (i.e. sensitivity) as a function of over threshold voltage Vₒᵥₑᵣ, and a curve 412 showing the dark count rate as a function of over threshold voltage Vₒᵥₑᵣ, consistent with the basic relationship illustrated in FIG. 4a.

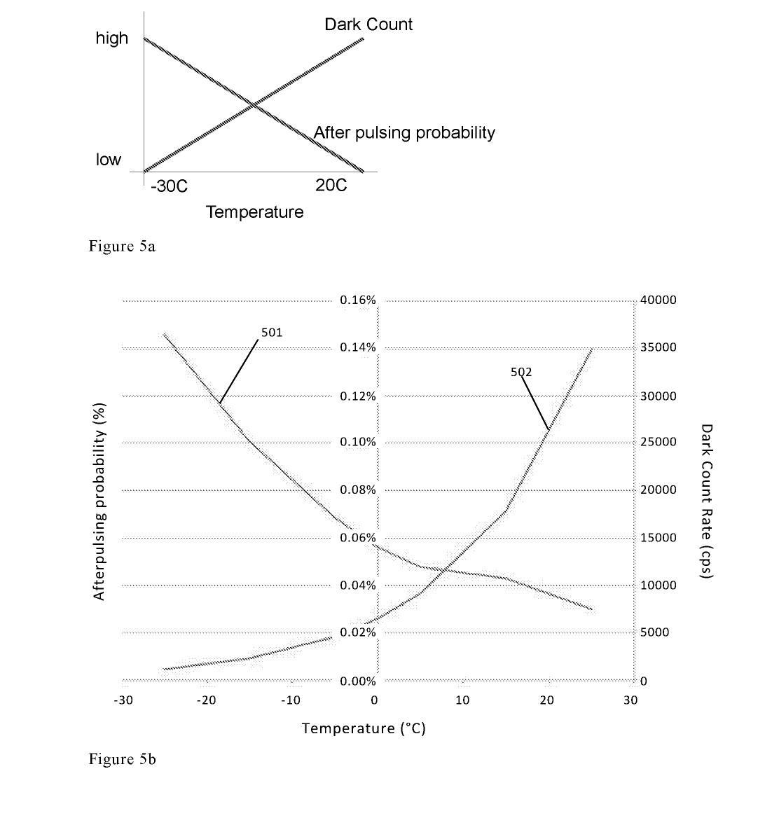

FIG. 5a shows the basic relationship between the temperature of the SPAD and the dark count and after pulsing probability. Cooling the SPAD allows a reduction in dark count at the expense of after pulse probability. The temperature of the SPAD is therefore typically set to suit the conditions to be measured by the photon counting system (low or high count rates).

FIG. 5b shows measured data comprising curve 501 showing peak after pulsing probability vs. temperature, and curve 502 showing dark count rate as a function of temperature, consistent with the basic relationship illustrated in FIG. 5a.

In view of these tradeoffs, known single photon counting systems are tuned for a particular application, and the system parameters (such as bias voltage, SPAD temperature, quenching mechanism and duration) are configured accordingly. For example, single photon counting systems may be optimised for low count rates or high count rates.

According to a first aspect of the invention, there is provided a single photon counting apparatus comprising a SPAD (single photon avalanche photodiode) and a controller; wherein
the controller is operable to vary the operating parameters of the SPAD during use in response to a count rate detected by the SPAD, the operating parameters comprising at least one of:
the voltage across the SPAD during an active period, the voltage across the SPAD during a quench period, the duration of the quench period and the temperature of the SPAD.

Such an apparatus has the ability to self tune the parameters of the SPAD to achieve a more optimal compromise of operating parameters, and therefore allows improved performance (e.g. lower noise, improved linearity etc) of the apparatus. Furthermore, such an apparatus has greater flexibility, in that it is suitable across a wider range of applications (from very low count rates to very high count rates). In addition, such a system can dynamically adjust the efficiency of the SPAD, thereby simplifying the apparatus by removing the need for an optical attenuator.

The controller may be configured to decrease the voltage across the SPAD during an active period in response to an increase in the count rate.

The controller may be configured to increase the voltage across the SPAD during an active period in response to a decrease in the count rate.

The controller may be configured to decrease the duration of the quench period in response to an increase in the count rate.

The controller may be configured to increase the duration of the quench period in response to a decrease in the count rate.

The controller may be configured to decrease the voltage across the SPAD during an active period in response to determining that the SPAD is saturated.

The controller may be configured to decrease the temperature of the SPAD in response to a decrease in count rate.

The controller may be configured to decrease the temperature of the SPAD in response to an increase in dark count.

The controller may be configured to increase the temperature of the SPAD in response to an increase in count rate.

The controller may be configured to increase the temperature of the SPAD in response to an increase after pulsing.

According to a second aspect of the invention, there is provided a particle characterisation instrument, comprising the apparatus of any preceding claim, wherein the apparatus is operable to detect light scattered by interactions with particles of a sample.

According to a third aspect of the invention, there is provided a particle characterisation instrument comprising a single photon counting system arranged to detect light scattered from particles of a sample, wherein the single photon counting system comprises a SPAD, and is operable to vary the operating parameters of the SPAD based on at least one of particle size, particle concentration, an intensity of illumination of the sample, and the count rate from the SPAD.

An initial set of operating parameters for the SPAD may be automatically selected by the instrument based on at least one of: an expected particle size, an expected particle concentration, and an intensity of sample illumination.

The instrument may be operable to perform a dynamic light scattering measurement and/or a zeta potential measurement.

Where the SPAD is configured to detect scattered light from the sample when performing a zeta potential measurement, the instrument may be configured to remove dark counts based on a correlation performed on the output of the SPAD. In response to a determination that a zeta potential measurement is to be performed, the readout circuit may be configured to: increase the voltage across the SPAD during an active period; increase the temperature of the SPAD; and/or to increase the duration of the quench period. The scattered light may be backscattered light.

Where the SPAD is configured to detect scattered light from the sample when performing a particle sizing measurement the instrument may be configured to remove dark counts based on a correlation performed on the output of the SPAD. In response to a determination that a particle sizing measurement is to be performed, the readout circuit is configured to: increase the voltage across the SPAD during an active period, increase the temperature of the SPAD, and/or to increase the duration of the quench period.

At least one embodiment of the present invention will now be described by way of example and with reference to the accompanying drawings in which:

FIG. 1 is a graph showing a quench cycle for a SPAD;

FIG. 2 is a graph showing the relationship between dead time and linearity of count rate;

FIG. 3a is a graph schematically illustrating the relationship between quench time and maximum count rate (without saturation), and between quench time and after pulse probability;

FIG. 3b is a graph of measured data from a SPAD showing the relationship between channel time and after pulsing probability;

FIG. 4a is a graph schematically illustrating the relationship between bias voltage and sensitivity, and between bias voltage and dark count;

FIG. 4b is a graph of measured data from a SPAD showing the relationship between bias voltage (over threshold voltage, Vₒᵥₑᵣ) and efficiency (or sensitivity), and between bias voltage and dark count rate;

FIG. 5a is a graph schematically illustrating the relationship between temperature and dark count rate, and between temperature and after pulsing probability;

FIG. 5b is a graph of measured data from a SPAD showing the relationship between temperature and dark count rate, and between temperature and after pulsing probability; and

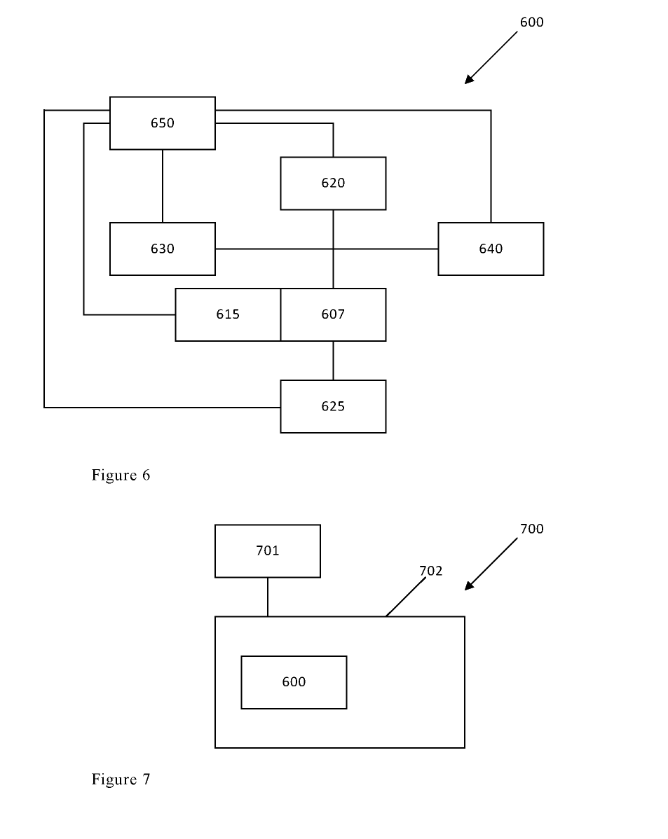

FIG. 6 is a block diagram of a single photon counting apparatus according to an embodiment of the invention;

FIG. 7 is a block diagram of a particle counting apparatus according to an embodiment of the invention; and

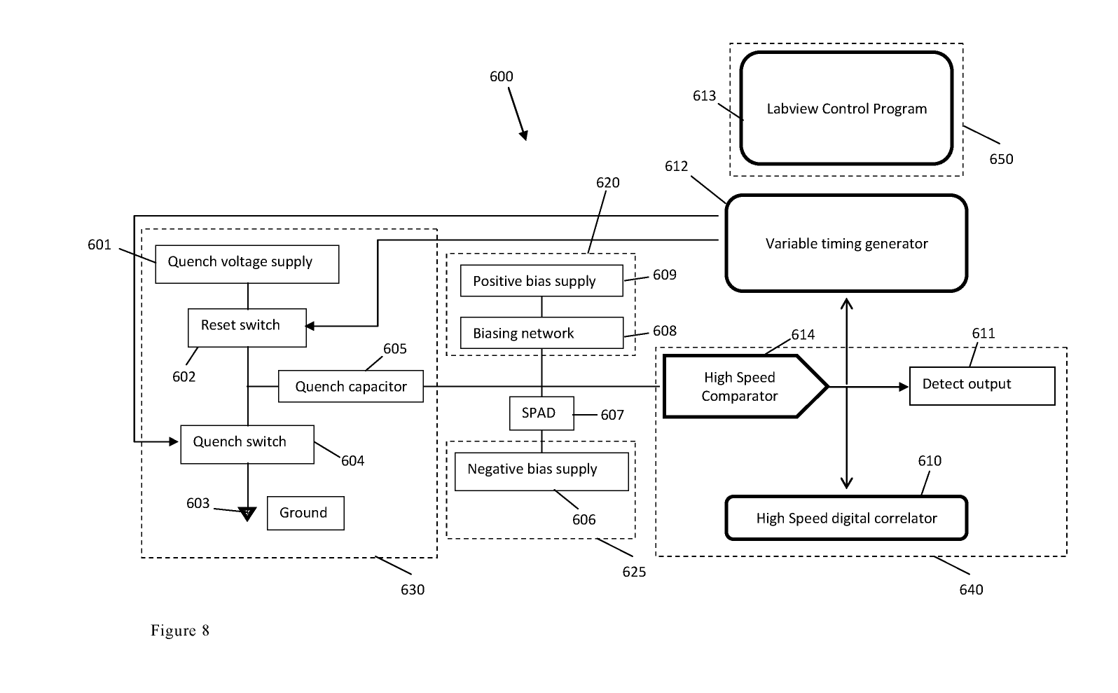

FIG. 8 is a further block diagram of a single photon counting apparatus according to an embodiment.

Referring to FIG. 6 and to FIG. 8, block diagrams of an example embodiment of a single photon counting apparatus 600 are shown. The apparatus 600 comprises a SPAD device 607, temperature control means 615 (in FIG. 6), positive biasing circuit 620, negative biasing circuit 625, quenching circuit 630, readout circuit 640 and controller 650.

The SPAD device 607 may be any appropriate SPAD device, such as a SAP500 Laser Components device, with a fibre optic pigtail having an fc-pc connector.

The SPAD 607 is in thermal contact with the temperature control means 615, which comprises a heating and/or cooling means, such as a thermoelectric module. The temperature control means 615 may further comprise a temperature controller, such as an Oven Industries temperature control (OI-5R7-001). The temperature control means 615 is operable to adjust the temperature of the SPAD 607, under the control of the controller 650.

The negative biasing circuit 625 comprises a negative bias supply 606, and is arranged to provide an adjustable negative voltage to the anode of the SPAD 607, under the control of the controller 650. The voltage applied to the anode of the SPAD 607 is the threshold voltage (Vₜₕ) of the SPAD 607 plus an excess voltage (Vₒᵥₑᵣ) that is selected to provide the appropriate performance. It is well known that there is a linear relationship between the threshold voltage of a SPAD and the temperature of the SPAD, and the temperature of the SPAD 607 and this relationship may be used by the controller 650 to determine the threshold voltage, so that the negative voltage at the anode for a particular value of Vₒᵥₑᵣ can be determined. In some embodiments the controller 650 may be operable to determine the threshold voltage for the SPAD 607 based on the temperature of the SPAD 607. The determination of the threshold voltage may comprise interpolating a table of values that define a relationship between the threshold voltage and the temperature of the SPAD 607. The voltage applied to the anode of the SPAD 607 by the negative biasing circuit 625 sets the voltage difference over the SPAD 607 during an active period.

The positive biasing circuit 620 comprises a positive bias supply 609 and a biasing network 608. The biasing network 608 is connected to the cathode of the SPAD 607, and sets the voltage at the input to the readout circuit 640 to just above its switching threshold, for instance by using a high speed Schottky diode and a high value passive quench resistor. The positive bias supply 609 is controlled by the controller 650, and may be set to a level that is small enough to suitably limit the avalanche current. The appropriate positive bias supply voltage may be determined by the controller 650 based on a value of a passive quench resistor and the value of Vₒᵥₑᵣ that is applied across the SPAD 607.

When a photon or dark count triggers an avalanche in the SPAD 607, the voltage on the SPAD cathode dips due to current flow through the passive quench resistor. This change in voltage causes the input to the comparator 614 to cross its switching threshold, generating a detect signal.

A correlator 610 may be provided for performing correlation on the counts from the comparator 614. The correlator 610 may receive detect signals from the comparator 614, and may be used in applications such as particle sizing by dynamic light scattering (DLS) and zeta potential measurement.

The detect signal from the comparator 614 is used to trigger the quench circuit 630 to quench the SPAD 607. The quench circuit 630 comprises a quench voltage supply 601, reset switch 602, quench capacitor 605 quench switch 604 and variable timing generator 612.

The quench capacitor 605 is connected at a first end to the cathode of the SPAD 607, and at a second end to the quench voltage supply 601, via the reset switch 602. A small trickle current is provided to the quench capacitor 605 via the reset switch 602 to maintain the voltage at the second end of the quench capacitor at the quench supply voltage 601. The quench switch 604 is operable to switch the second end of the quench capacitor 605 to ground, which results in a voltage drop at the first end of the quench capacitor 605. This reduces the voltage across the SPAD 607. The quench supply voltage 601 is selected to ensure that this voltage drop results in the voltage across the SPAD 607 dropping below the threshold voltage Vₜₕ, thereby quenching the avalanche event. After a first quench delay, set by the variable timing generator 612, the quench switch 604 is turned off. After a second quench delay, set by the variable timing generator 612, the reset switch 602 is switched on to re-charge the second end of the quench capacitor 605. The re-charging of the second end of the quench capacitor 605 results in an increase in voltage at the first end of the quench capacitor 605, which in turn brings the voltage difference across the SPAD 607 to above the threshold voltage Vₜₕ, ready for the next avalanche event. The quench time is the sum of the first and second quench delays.

In some embodiments, the duration of the first and second quench delays may be selected to take account of different timing required by the reset switch 602 and the quench switch 604, which may comprise switching elements such as junction transistors or field effect transistors. Junction transistors may be used for both the reset switch 602 and the quench switch 604. The variable timing generator 612 may comprise an analogue circuit comprising a voltage ramp generator and a dual level comparator for generating the two timing signals.

In other embodiments the timing circuit may be implemented using discrete logic, or embedded within a field programmable gate array (FPGA). An FPGA device may be large enough to completely implement both the timing generator 612 and the high speed digital correlator 610. FPGA devices such as the Xlinx Spartan or Zynq parts may be suitable for this approach.

Regardless of the details of the implementation of the quench circuit 630, the quench circuit 630 is operable to provide a quench time and/or quench voltage that is adjustable, under the control of the controller 650. In some embodiments the adjustment of the quench time may be achieved by adjusting at least one of the first and second quench delay.

A readout circuit 640 is provided, for detecting avalanche events in the SPAD 607 and providing an output based on the count of avalanche events. The controller 650 receives the output of the readout circuit 640, so that the controller 650 can adjust the quench time, quench voltage supply 601, positive bias supply 609, and negative bias supply 606, based on the count rate reported by the readout circuit 640. The readout circuit 640 may comprise a high speed digital correlator 610, for correlating the avalanche events. In the context of particle characterisation, the light incident on the SPAD 607 may be scattered light from illuminating particles in a sample. The correlator may auto correlate avalanche events. Dark count may thereby be at least partially rejected.

The controller 650 may comprise a computer running control and analysis software such as Labview® for controlling the photon counting apparatus. In other embodiments, the controller 650 may be implemented in firmware on an embedded microcontroller/microprocessor. For instance, in the context of particle analysis, the controller may allow a user to select a particular sample type or analysis type. The controller may subsequently be operable to set the initial operating parameters of the photon counting apparatus 600 appropriately, for instance based on control rules. The controller 650 may provide a user interface for adjusting the control rules.

Furthermore, the controller 650 preferably implements dynamic control of the operating parameters of the photon counting apparatus, so that at least one of the voltage across the avalanche photodiode during an active period, the voltage across the avalanche photodiode during a quench period, the duration of the quench period and the temperature of the avalanche photodiode are adjustable during use. The controller 650 preferably adjusts the operating parameters of the photon counting apparatus 600 based on the count rate, but other factors may be used in addition to the count rate.

Referring to FIG. 7, a particle characterisation instrument 700 is shown, comprising a single photon counting apparatus 600 according to an embodiment. The particle characterisation apparatus may comprise a user interface 701, by which a user may control the operation of the instrument, including the single photon counting apparatus 600. The particle characterisation apparatus may be operable to perform a dynamic light scattering (DLS) measurement on a sample. When using DLS to measure low concentrations of small particles (typically around 1 nm or less) the amount of scattered light will be very small, giving only a few thousand photons per second. On the opposite end of the scale, larger particles of 1 μm and larger in high concentrations will give very large photon count rates in the millions per second.

A single photon counting system which cannot be adjusted according to particle size, concentration or incident laser illumination will be limited in the range of size of particles, concentrations and measurement times that it can measure. The use of an adjustable photon counting apparatus according to an embodiment allows the appropriate parameters for a particular analysis to be selected by a user, or determined automatically by the instrument or apparatus. Determining appropriate parameters automatically may comprise adjusting parameters based on a count rate, and/or selecting parameters based on expected properties of the sample, such as sample concentration and particle size.

For low light scattering measurements the performance of a single photon counting apparatus will be dominated by the dark count, sensitivity and after pulsing performance which in turn affects the accuracy and speed of the measurement. For high light scattering measurements the performance of a single photon counting apparatus will be dominated by dead time.

A single photon counting apparatus according to an embodiment can improve the dynamic range in a particle sizing application by increasing the voltage across the SPAD during an active period, reducing the temperature and increasing quench time for weak light scattering measurements. This will increase sensitivity and reduce after pulsing at the cost of dead time. However since the photon count rates are very small, the system will still be in its linear region of count rate vs incident photons. Due to an increase in sensitivity more of the incident photons will be counted and the measurement can be completed more quickly.

For the case of large particles and high concentrations, which give a strong scattered light, the photon counting apparatus can be adjusted by decreasing the SPAD voltage, increasing temperature and decrease quench time therefore decreasing the dead time of the single photon counting apparatus. This will increase the linearity of the detector and hence be able to cope with a larger amount of incident photons.

Zeta potential of nano particles such as proteins can be measured using NIBS (Non Invasive Back Scattering). The technique measures very small amounts of photons scattered back towards an incident laser source but at the lower end of its measurement range after pulsing from SPADs occurs with the same timing as the signal from the particle measured. Since the afterpulses are time correlated to previous scattered photons they cannot be removed by correlation and create a false measurement signal. However, dark counts, which are random and uncorrelated to previous scattered photons, will not appear as a measured signal in a correlogram and so do not corrupt the signal.

By using a single photon counting apparatus according to an embodiment, the operating parameters of the SPAD may be adjusted, e.g. increasing the bias voltage, temperature and quench time. It is thereby possible to greatly reduce the amount of after pulsing in this low count rate measurement scenario, at the expense of dead time and dark counts, thus greatly improving the signal quality. Linearity should not be significantly affected due to the low count rate.

Embodiments of the present invention may also have applications in the areas of; Raman spectroscopy (e.g. Fourier transform Raman), light detection, laser range finding, photon counting, data communications, optical tomography, light detection and ranging (LIDAR), and fluorescence detection.

A number of other modifications may be made to the example embodiments, without departing from the scope of the invention, as defined by the appended claims.

1. A single photon counting apparatus comprising a SPAD and a controller; wherein
the controller is operable to vary the operating parameters of the SPAD during use in response to a count rate detected by the SPAD, the operating parameters comprising at least one of:
the voltage across the SPAD during an active period, the voltage across the SPAD during a quench period, the duration of the quench period and the temperature of the SPAD.

2. The apparatus of claim 1, wherein the controller is configured to decrease the voltage across the SPAD during an active period in response to an increase in the count rate.

3. The apparatus of claim 1, wherein the controller is configured to increase the voltage across the SPAD during an active period in response to a decrease in the count rate.

4. The apparatus of claim 1, wherein the controller is configured to decrease the duration of the quench period in response to an increase in the count rate.

5. The apparatus of claim 1, wherein the controller is configured to increase the duration of the quench period in response to a decrease in the count rate.

6. The apparatus of claim 1, wherein the controller is configured to decrease the voltage across the SPAD during an active period in response to determining that the SPAD is saturated.

7. The apparatus of claim 1, wherein the controller is configured to decrease the temperature of the SPAD in response to an increase in dark count.

8. The apparatus of claim 1, wherein the controller is configured to increase the temperature of the SPAD in response to an increase in after pulsing.

9. A particle characterization instrument, comprising the apparatus of claim 1, wherein the apparatus is operable to detect light scattered by interactions with particles of a sample.

10. A particle characterization instrument comprising a single photon counting system arranged to detect light scattered from particles of a sample, wherein the single photon counting system comprises a SPAD, and is operable to vary the operating parameters of the SPAD based on at least one of particle size, particle concentration, an intensity of illumination of the sample, and the count rate from the SPAD.

11. The instrument according to claim 9, wherein an initial set of operating parameters for the SPAD are automatically selected by the instrument based on at least one of: an expected particle size, an expected particle concentration, and an intensity of sample illumination.

12. The instrument according to claim 9, wherein the instrument is operable to perform a dynamic light scattering measurement and/or a zeta potential measurement.

13. The instrument according to claim 12, wherein:
the SPAD is configured to detect scattered light from the sample when performing a zeta potential measurement;
the instrument is configured to remove dark counts based on a correlation performed on the output of the SPAD; and
in response to a determination that a zeta optional measurement is to be performed, the readout circuit is configured to: increase the voltage across the SPAD during an active period, increase the temperature of the SPAD, and/or to increase the duration of the quench period.

14. The instrument according to claim 12, wherein:
the SPAD is configured to detect scattered light from the sample when performing a particle sizing measurement;
the instrument is configured to remove dark counts based on a correlation performed on the output of the SPAD; and
in response to a determination that a particle sizing measurement is to be performed, the readout circuit is configured to: increase the voltage across the SPAD during an active period, increase the temperature of the SPAD, and/or to increase the duration of the quench period.
